(19) United States
(12) Patent Application Publication
(10) Pub. No.: US 2013/0135804 A1
(43) Pub. Date: May 30, 2013

(54) FRAME HOUSING AND DISPLAY DEVICE

(71) Applicants: Yoshihiro Takechi, Tokyo (JP); Yoshinobu Moriya, Tokyo (JP)

(72) Inventors: Yoshihiro Takechi, Tokyo (JP); Yoshinobu Moriya, Tokyo (JP)

(21) Appl. No.: 13/809,148

(22) PCT Filed: Jul. 15, 2010
(86) PCT No.: PCT/JP2010/061969

§ 371 Date: Jan. 8, 2013

(51) Int. Cl. H05K 5/00

(52) U.S. Cl. CPC H05K 5/0017
USPC 361/679.01

(57) ABSTRACT

A frame housing is provided on a peripheral surface of a display unit. The frame housing includes: a plurality of divided frames including a plurality of attachment portions including a through hole used for screw-fastening to a screw hole provided in the peripheral surface of the display unit. The through hole is an oblong hole with a long-axis direction of the oblong hole arranged in a direction along the peripheral surface of the display unit.

### TECHNICAL FIELD

The present invention relates to a frame housing provided on a peripheral surface of a display unit and a display device that includes the same.

### BACKGROUND ART

A display device such as a liquid crystal display or plasma display is conventionally constituted by attaching various frame housings to the peripheral surface of a rectangular plate-shaped display unit. Also, there is a constitution in which a plurality of divided frames that are divided in the peripheral direction of the frame (display unit) are connected to the frame housing, and attached by being screw fastened to the peripheral surface of the display unit (for example, refer to Patent Document 1).

Moreover, the plurality of divided frames are each formed with plastic in an L shape, and a plurality of through holes for screw fastening to the peripheral surface of the display unit are formed at a predetermined spacing in the peripheral direction (long-side direction), and also at a predetermined spacing in the width direction (short-side direction). When the divided frames that are formed in this manner are installed on the peripheral surface of the display unit, the through holes and screw holes that are formed in the peripheral surface of the display unit are in communication, and by inserting countersunk screws in these through holes and screw holes and screwing them to a predetermined torque, they are integrally attached to the display unit.

### PRIOR ART DOCUMENT

### Patent Document

[Patent Document 1] Japanese Unexamined Patent Application, first Publication No. 2008-249926

### SUMMARY OF THE INVENTION

### Problem to be Solved by the Invention

However, in the aforementioned conventional frame housing and display device, since thermal deformation occurs in the divided frames due to variations in the ambient temperature, the positions of the through holes and the screw holes of the display unit end up being shifted in the state of the divided frames being installed on the peripheral surface of the display unit during assembly, and so attachment of the divided frames may not be possible, or stress may arise in the divided frames that have been screw fastened. Also, since the expansion and contraction amount due to the thermal deformation increases as the length of the divided frames becomes longer, particularly in frame housings (divided frames) that correspond to display devices of 52 inches, 55 inches or larger, the positional shifting of the through holes and screw holes of the display unit easily occurs, and so problems may arise during the assembly process.

Moreover, even after attaching the divided frames to the display unit, thermal deformation occurs in the frame housing due to the heat generated during operation of the display device and changes in the ambient temperature, leading to the generation of stress in the frame housing.

In addition, in the aforementioned conventional frame housing and display device, since the divided frames are constituted to be attached to the display unit using countersunk screws, when they are tightened with a force greater than the specified torque, the countersunk screws end up passing through the divided frames with a thin wall made of plastic, and in the worst case, it becomes necessary to replace the divided frames.

The present invention has been achieved in view of the aforementioned circumstances, and has as its object to provide a frame housing enabling divided frames to be favorably attached to a display unit by screw fastening even in the case of thermal deformation having occurred in the divided frames, and also enabling suppression of the generation of stress caused by the thermal deformation, and a display device that includes it.

### Means for Solving the Problem

In order to attain the aforementioned object, this invention provides the following means.

A frame housing of the present invention is provided on a peripheral surface of a display unit, and includes: a plurality of divided frames that are each formed in an L-shape, the divided frames being formed by providing with a plurality of attachment portions including a through hole used for screw-fastening to a screw hole formed in the peripheral surface of the display unit, and the through hole being formed as an oblong hole with a long-axis direction thereof arranged in a direction along the peripheral surface of the display unit.

In this invention, since the through hole that is formed in the attachment portions of the divided frames are an oblong hole, even in the case of expansion or contraction having occurred in the divided frames due to thermal changes, it is possible to reliably bring the through hole of the divided frames and the screw hole of the display unit into communication, and so it becomes possible to readily perform the assembly work by inserting/screwing the screw into these through hole and the screw hole. Moreover, since the through hole and the screw hole are reliably in communication in this way, and the through hole is an oblong hole, even in the case of thermal deformation having occurred in the divided frames, it is possible to suppress the occurrence of stress.

Also, in this invention it is preferable that it is constituted with providing a screw that is inserted into the through hole of the attachment portions and screwed into the screw hole of the display unit, and attaches the divided frames to the peripheral surface of the display unit, and the screw is a screw in which a bottom surface of a head portion is formed in a planar shape.

In this invention, since the screw for fixing the divided frames is a screw such as a flat-head screw in which the bottom surface of the head portion has a planar shape, it is possible to screw fasten the divided frames to the display unit by the planar bottom surface of the head portion presses and contacts the outer surface of the divided frames. For that reason, it is possible to favorably fix and attach the divided frames to the display unit without the screw passing through the divided frames having thin walls made of plastic when tightened with a force greater than the specified torque as in the conventional case of using countersunk screws.

Moreover, in the frame housing of the present invention, it is more preferable that the attachment portions are formed by including a plurality of through holes of: a protective glass installation through-hole used when installing a protective glass on a front surface of the display unit; and a normal-use through hole used when not installing the protective glass, and the protective glass installation through-hole is formed so that a length of a short axis thereof is less than a length of a short axis of the normal-use through hole.

In this invention, since the protective glass installation through-hole is formed with the length of the short axis thereof less than that of the normal-use through hole, when screw fastening by using the protective glass installation through-hole, it is possible to eliminate (reduce) the play in the width direction of the divided frames between the screw and the protective glass installation through-hole. Thereby, in the state of a predetermined gap being opened between the protective glass that is provided on the front surface of the display unit, and the side end portion of the divided frames that are arranged on the front surface side of the protective glass (the distal end portion of the turned back wall portion), it is possible to reliably fix the divided frames to the display unit, and it is possible to prevent the side end portions of the divided frames from coming into contact with the protective glass 30 and thereby causing damage.

Also, in the frame housing of the present invention, it is more preferable that the attachment portions are formed by including: a fitting recessed portion that is recessed from an outer surface of the divided frames toward an inner surface of the divided frames and fits a concealed label; a screw head housing recessed portion that is recessed from a bottom surface of the fitting recessed portion toward the inner surface of the divided frame and houses a head portion of a screw; and the through holes that pass through from the bottom surface of the screw head housing recessed portion to the inner surface of the divided frames.

In this invention, by setting up the concealed label to fit in the fitting recessed portion, it is possible to prevent the through hole and the screw from being exposed to the outside, and possible to enhance the design properties of the display device. Also, in the case of being constituted in this manner, it is possible to make the outer surface of the concealed label flush with the outer surface of the divided frames, and since the head portion of the screw does not project to the outside from the outer surface of the divided frames, it is possible to favorably use the display device, which includes this frame housing attached to the display unit, for multi-displays and the like.

Moreover, in the frame housing of the present invention, it is preferable that the divided frames are constituted so that connection portions that are formed with thin walls projecting out in the peripheral direction of the display unit being provided at both end portion sides, and adjacent divided frames connect with the mutual connection portions being overlapped, and the divided frames are constituted so as to include: an engagement convex portion that is provided at one end portion side of the divided frames, and projects from a distal end of the connection portion in the peripheral direction of the display unit; and an engagement concave portion that is provided at an other end portion side of the divided frames, and indents from a base end of the connection portions to the inside in the peripheral direction, and are constituted so that the adjacent divided frames connect with the mutual engagement convex portion and the engagement concave portion being engaged.

In this invention, along with the connection portions, the engagement convex portion and the engagement concave portion are provided at the end portions of the divided frames. For this reason, when arranging the divided frames along the peripheral surface of the display unit, by installing the adjacent divided frames so that the connection portions of the divided frames overlap, while the engagement convex portion engaging with the engagement concave portion, mis-insertion of adjacent divided frames can be prevented. Thereby, it is possible to readily install each of the divided frames at predetermined positions, and possible to favorably connect the adjacent divided frames.

The display device of the present invention is constituted with any of the aforementioned frame housings, and the display unit.

In this invention, it is possible to obtain the function effect of the aforementioned frame housing.

### Effect of the Invention

In the frame housing of the present invention and the display device that includes it, since the through hole that is formed in each attachment portion of the divided frames is an oblong hole, even in the case of expansion or contraction having occurred in the divided frames due to thermal changes, it is possible to reliably bring the through hole of the divided frames and the screw hole of the display unit into communication, and so it is possible to readily perform the assembly work by inserting/screwing the screws into the through hole and the screw hole. Moreover, since the through hole and the screw hole are reliably in communication in this way, and the through hole is an oblong hole, even in the case of thermal deformation having occurred in the divided frames, it is possible to suppress the occurrence of stress.

Thereby, it is possible to achieve an improvement in the manufacturing yield, and possible to achieve an improvement in the reliability of the display device.

### BRIEF DESCRIPTION OF THE DRAWINGS

FIG. 1 is a perspective view that shows a display device according to one exemplary embodiment of the present invention.

FIG. 2 is an exploded perspective view that shows the display device according to the one exemplary embodiment of the present invention.

FIG. 3 is a plan view that shows a divided frame of a frame housing according to the one exemplary embodiment of the present invention.

FIG. 4 is a side view that shows the divided frame of the frame housing according to the one exemplary embodiment of the present invention.

FIG. 5 is a perspective view that shows connection portions of the divided frames according to the one exemplary embodiment of the present invention.

FIG. 6 is a perspective view that shows the connection portions of the divided frames according to the one exemplary embodiment of the present invention.

FIG. 7 is a plan view that shows an attachment portion of the divided frame according to the one exemplary embodiment of the present invention.

FIG. 8 is a cross-sectional view that shows the attachment portion of the divided frame according to the one exemplary embodiment of the present invention.

FIG. 9 is a plan view that shows through holes of the attachment portion of the divided frame according to the one exemplary embodiment of the present invention.

FIG. 10 is a cross-sectional view that shows the through holes of the attachment portion of the divided frame according to the one exemplary embodiment of the present invention.

FIG. 11 is a cross-sectional view that shows the display device according to the one exemplary embodiment of the present invention, being a view that shows the case of protective glass being provided on the display unit.

FIG. 12 is a cross-sectional view that shows the display device according to the one exemplary embodiment of the present invention, being a view that shows the case of protective glass not being provided on the display unit.

### EMBODIMENTS FOR CARRYING OUT THE INVENTION

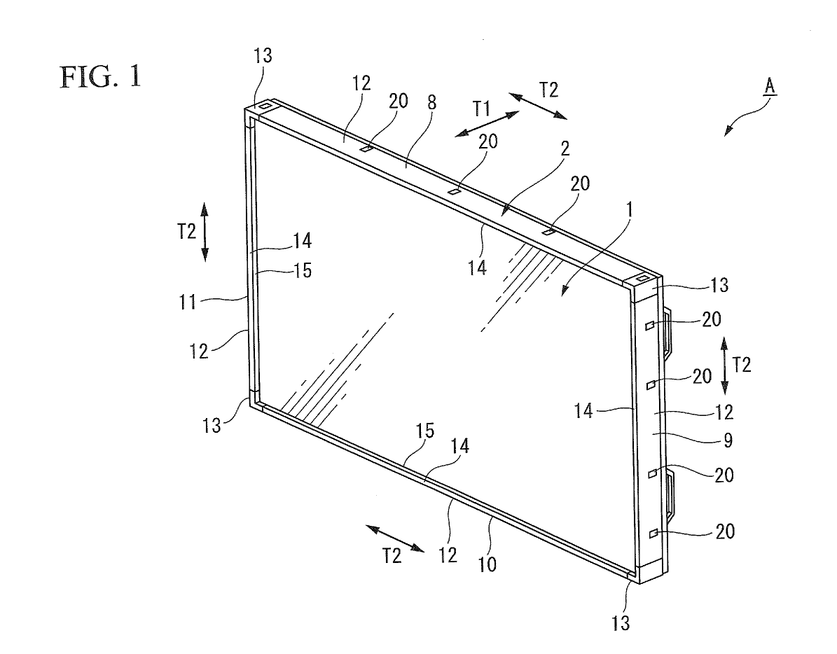

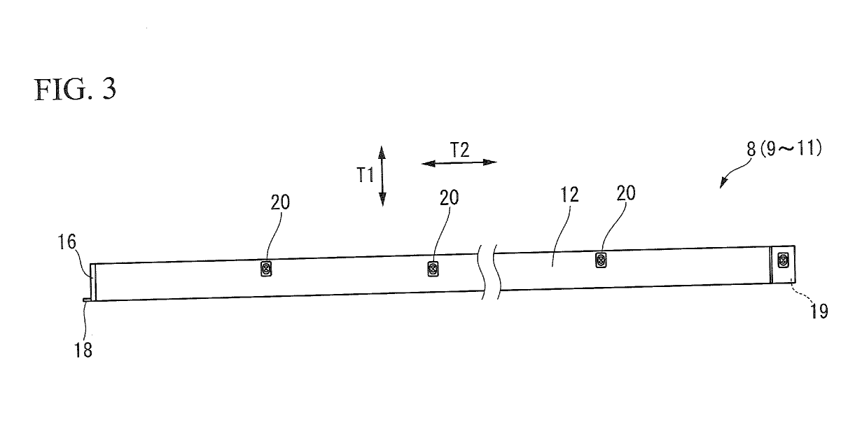

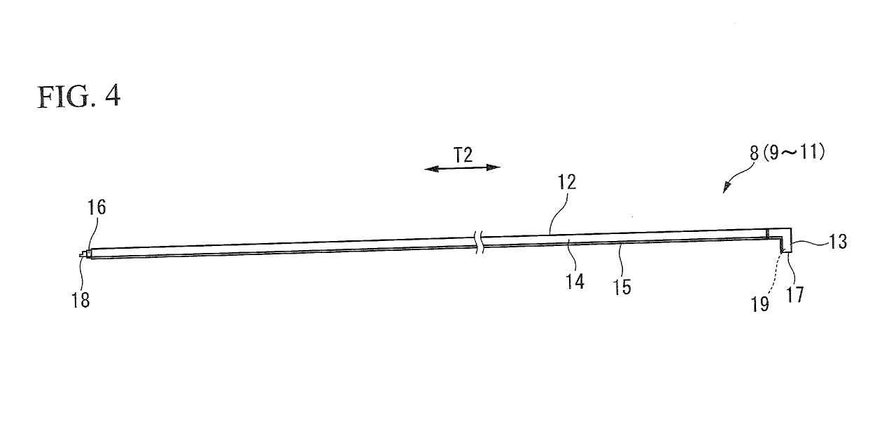

Hereinbelow, the frame housing according to one exemplary embodiment of the present invention and a display device including the same shall be described with reference to FIG. 1 to FIG. 12.

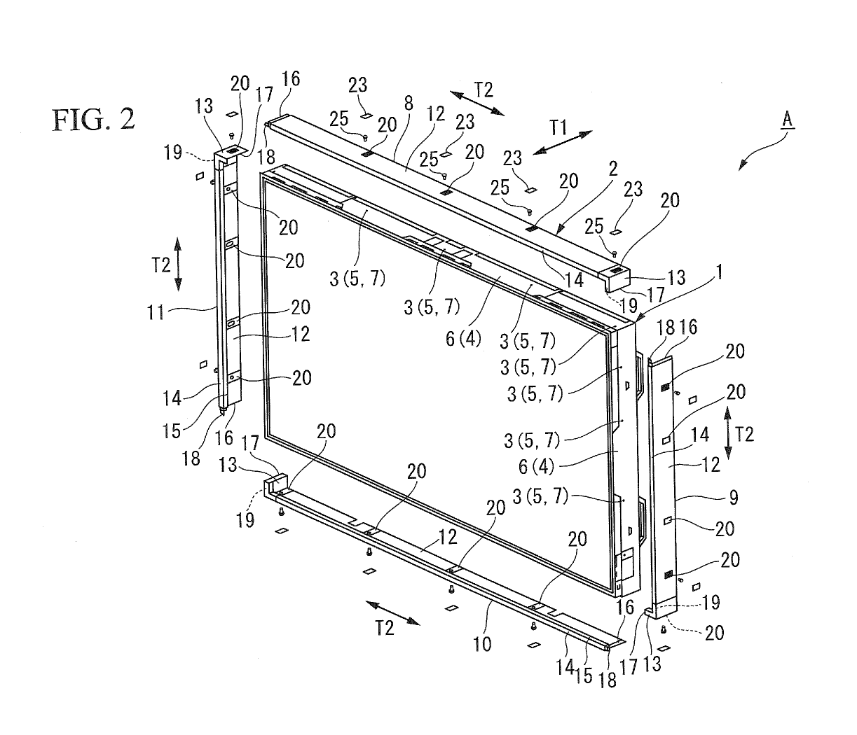

As shown in FIG. 1 and FIG. 2, a display device A of the present exemplary embodiment is constituted by including a display unit 1 having a rectangular plate shape, and a frame housing 2 having a rectangular annular shape that is integrally attached to cover the entire peripheral surface of this display unit 1.

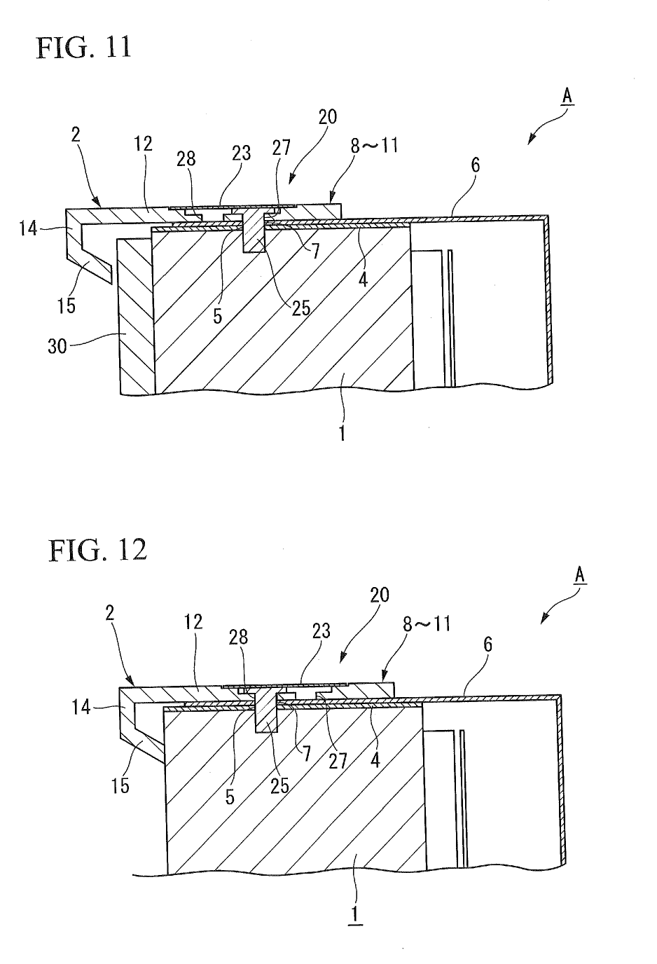

The display unit 1 is constituted by a liquid crystal, plasma type display, or the like, and on the peripheral surface thereof, as shown in FIG. 2, screw holes 3 are formed at a predetermined spacing in the peripheral direction T2 approximately in the center of the thickness direction T1. Also, a protective frame 4 made of metal and having a rectangular annular shape for protecting the display unit 1 is attached to the peripheral surface of the display unit 1, and this protective frame 4 is disposed in the frame housing 2 (refer to FIG. 11). In the protective film 4 is formed a communication hole 5 that communicates with the screw hole 3 of the display unit 1 in the state of being attached to the display unit 1.

Also, an L-shaped back cover 6 is attached to the surface of the protective frame 4, and in this back cover 6 is formed a communication hole 7 that communicates with the screw hole 3 of the display unit 1 and the communication hole 5 of the projective film 4 in the state of being attached to the display unit 1 (refer to FIG. 12). Thereby, the peripheral surface of the display unit 1 is formed by the back cover 6.

The frame housing 2 of the present exemplary embodiment, as shown in FIG. 1 to FIG. 4, is divisibly formed in the peripheral direction T2 by including divided frames 8, 9, 10, 11 made of plastic. Also, these divided frames 8 to 11 are each formed in an L-shape so as to engage with the corner portion of the display unit 1, by including a long base portion 12 that, in the state of being attached to the display unit 1, extends from the corner of the display unit 1 so as to cover the peripheral surface, and a short base portion 13 that extends from the corner portion of the display unit 1 so as to cover a portion of the corner portion side of the peripheral surface and to be perpendicular to the long base portion 12. That is to say, the divided frames 8 to 11 that are each formed in an L-shape are integrally formed so as to make the length dimension of the short base portion 13 shorter than the long base portion 12, and so that the long base portion 12 and the short base portion 13 are perpendicular to each other.

Also, at one side end portion in the width direction T1 of the long base portion 12 and the short base portion 13, a front wall portion 14 that extends in a direction perpendicular to the long base portion 12 and the short base portion 13 is provided over the entire length of the one side end portion. Moreover, at the side end portion side in the width direction of the front wall portion 14, a turned back wall portion 15 that is turned back by a predetermined angle is provided. Thereby, each divided frame 8 to 11 that includes the long base portion 12, the short base portion 13, the front wall portion 14 and the turned back wall portion 15 is formed in an approximate L-shape in cross section.

Also, as shown in FIG. 2 to FIG. 6, connection portions 16 and 17 for connecting adjacent divided frames 8 to 11 are provided at the end portions in the peripheral direction T2 of the long base portion 12 and the short base portion 13 and both end portions in the peripheral direction T2 of the front wall portion 14 (the end portions of the divided frames 8 to 11). These connection portions 16 and 17 are formed projecting out from the end portions of the long base portion 12 and the short base portion 13 and both end portions of the front wall portion 14 to the outer side in the peripheral direction T2, and formed with a thickness dimension that is less than the thickness of the long base portion 12, the short base portion 13, and the front wall portion 14 (for example, a thickness direction of half).

Also, at this time, the connection portion 16 that is provided at either one end portion of the long base portion 12 and the short base portion 13, and the one end portion of the front wall portion 14 at this one end portion side is formed projecting to the outside in the peripheral direction with the inner surface thereof flush with the inner surface of the long base portion 12, the short base portion 13 and the front wall portion 14. Also, the connection portion 17 that is provided at the other end portion of the long base portion 12 and the short base portion 13 and the other end portion of the front wall portion 14 at this other end portion side is formed projecting to the outside in the peripheral direction T2 with the outer surface thereof flush with the outer surface of the long base portion 12, the short base portion 13 and the front wall portion 14. By causing the connection portions 16 and 17 of the divided frames 8 to 11 that are formed in this manner to engage in a vertically overlapping manner, the divided frames 8 to 11 that are adjacent in the peripheral direction T2 are integrally connected.

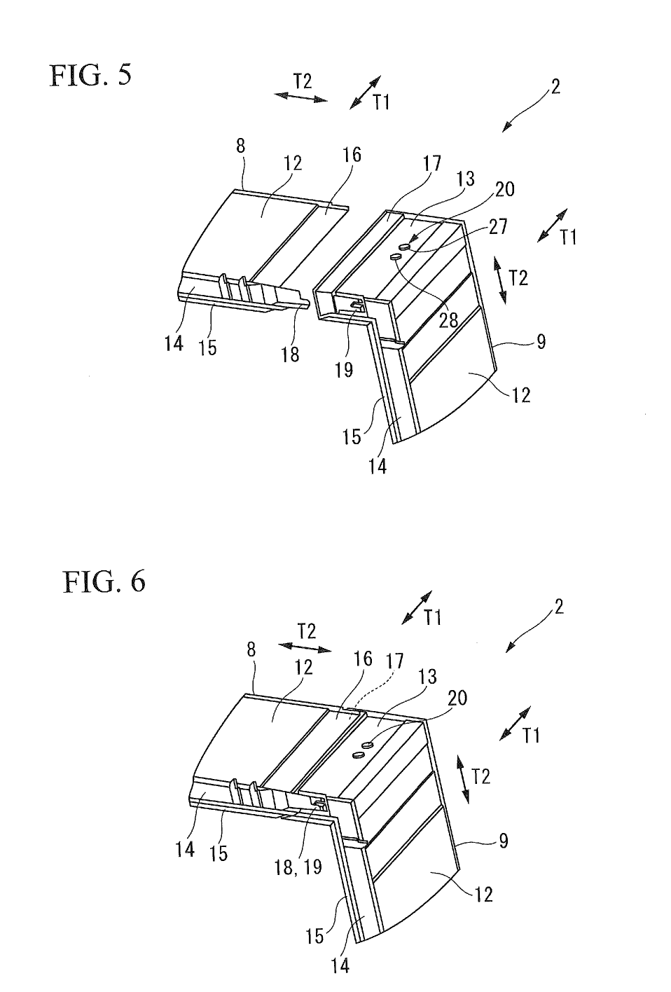

Moreover, as shown in FIG. 5 and FIG. 6, the divided frames 8 to 11 of the present exemplary embodiment are formed by including an engagement convex portion 18 that projects to the outside in the peripheral direction T2 from the distal end of one connection portion 16 of the front wall portion 14, and an engagement concave portion 19 that indents to the inside in the peripheral direction T2 from the base end of the other connection portion 17 of the front wall portion 14. By causing the connection portions 16 and 17 of the divided frames 8 to 11 to engage so as to vertically overlap, when integrally connecting the divided frames 8 to 11 that are adjacent in the peripheral direction, the engagement convex portion 18 engages with the engagement concave portion 19, whereby the divided frames 8 to 11 are guided to predetermined positions and connected, and mis-insertion (misconnection) is prevented. Also, at this time, the engagement convex portion 18 and the engagement concave portion 19 are formed so that a predetermined gap is formed between the distal end of the engagement convex portion 18 and the bottom portion of the engagement concave portion 19, in the state of the divided frames 8 to 11 being integrally connected.

Moreover, as shown in FIG. 1 to FIG. 3, attachment portions 20 for screw fastening the divided frames 8 to 11 to the display unit 1 are provided at predetermined positions of the short base portion 13 or the base end side of the long base portion 12 that connects to the short base portion 13, and the long base portion 12, that is to say, at positions corresponding to the screw holes 3 of the display unit 1 and the communication holes 5 and 7.

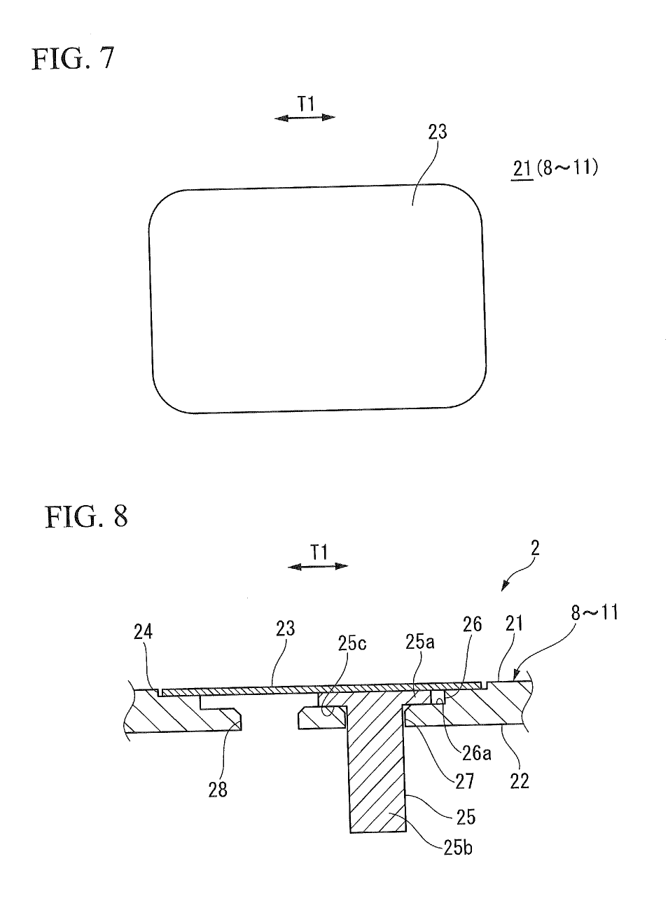

These attachment portions 20 are, as shown in FIG. 7 to FIG. 10, formed by including a fitting recessed portion 24 that is recessed from an outer surface 21 of each divided frame 8 to 11 toward an inner surface 22 and allows the fitting of a concealed label 23, and a screw head housing recessed portion 26 that is recessed further toward the inner surface 22 side from the fitting recessed portion 24 and houses a head portion 25a of a screw 25. Moreover, in each attachment portion 20, through holes 27 and 28 that pass through from a bottom surface 26a of the screw head housing recessed portion 26 to the inner surface 22 of the divided frames 8 to 11 in order to insert the shaft portion 25b of the screw 25 are arranged side-by-side at a predetermined spacing in the width direction T1 of the divided frames 8 to 11.

Then, in the present exemplary embodiment, in the state of the divided frames 8 to 11 being arranged at predetermined positions of the peripheral surface of the display unit 1, either of the through holes 28 (27) of each attachment portion 20 communicate with the screw hole 3 that is provided at predetermined position of the display unit 1, and by inserting and screwing the screw 25 into the through hole 28 (27) and the screw hole 3, the divided frames 8 to 11 are attached to the peripheral surface of the display unit 1. Also, the concealed label 23 is fitted and attached to the fitting recessed portion 24 of each attachment portion 20, and by this concealed label 23, exposure of the through holes 27 and 28 of the attachment portion 20 and the screw 25 to the outside, and thus impairment of the design of the display device A, is prevented.

Here, in the present exemplary embodiment, for example, the thickness of the divided frames 8 to 11 is set to be 3 mm, the thickness of the fitting recessed portion 24 and the concealed label 23 is set to be 0.5 mm, the thickness of the screw head housing recessed portion 26 is set to be 1.0 mm, and the length of the through holes 27 and 28 is set to be 1.5 mm. Thereby, the attachment portion 20 of the divided frames 8 to 11 is formed so that the outer surface of this concealed label 23 and the outer surface 21 of the divided frame 8 to 11 become flush in the state of the concealed label 23 being fitted in the fitting recessed portion 24.

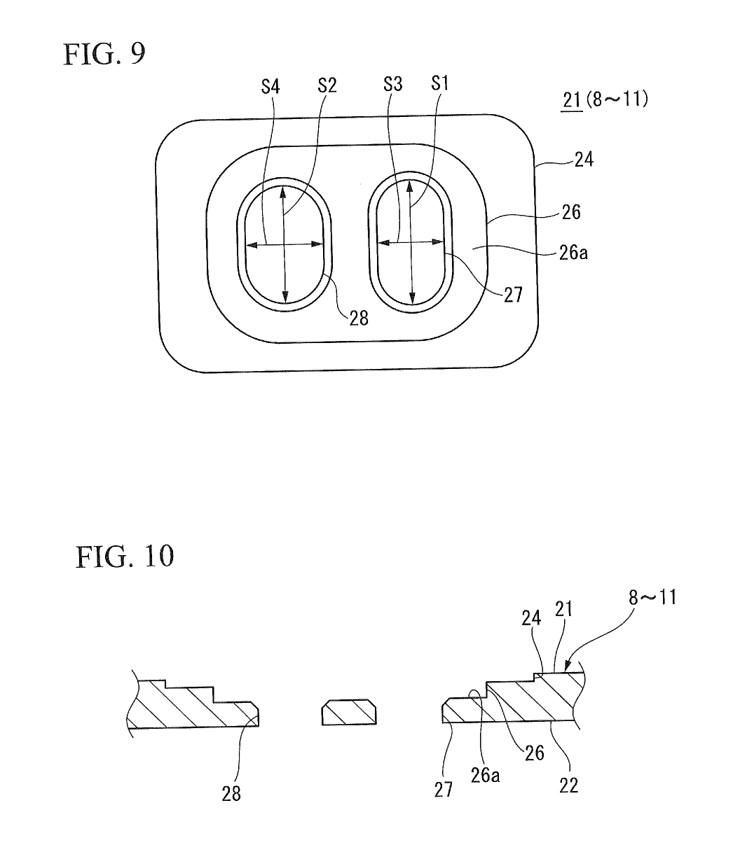

On the other hand, in the present exemplary embodiment, as for the two through holes 27 and 28 that are formed in the attachment portion 20, as shown in FIG. 9 to FIG. 12, the one through hole 27 serves as a protective glass installation through-hole that is used when providing protective glass 30 on the front surface of the display unit 1 (refer to FIG. 11), while the other through hole 28 serves as a normal-use through hole that is used when the protective glass 30 is not provided (refer to FIG. 12). Also, in the present exemplary embodiment, these through holes 27 and 28 are formed as oblong holes and not conventional round holes, and are formed with the directions of their respective long axes S1 and S2 facing the peripheral direction.

Moreover, as shown in FIG. 9, the protective glass installation through-hole 27 is formed so that the length of its short axis S3 is less than the length of the short axis S4 of the normal-use through hole 28.

Moreover, in the present exemplary embodiment, as the screw 25 for attaching the frame housing 2 to the display unit 1, as shown in FIG. 8, a screw, such as a flat-head screw or pan-head screw, of which the bottom surface 25c of the head portion 25a makes surface contact and abuts the bottom surface 26a of the screw head housing recessed portion 26, that is, a screw in which the bottom surface 25c of the head portion 25a is formed as a planar surface, is used.

Next, a method of attaching the frame housing 2 of the present exemplary embodiment that has the aforementioned constitution to the display unit 1 shall be described, and action and effect of the frame housing 2 of the present exemplary embodiment and the display device A that includes it shall be described.

First, the divided frames 8 to 11 are installed along the surface of the back cover 6 that constitutes the peripheral surface of the display unit 1. At this time, the adjacent divided frames 8 to 11 are installed so that the connection portions 16 and 17 of the divided frames 8 to 11 overlap, while causing the engagement convex portion 18 to engage with the engagement concave portion 19. Thereby, the divided frames 8 to 11 are arranged at predetermined positions in the state of the long base portion 12 and the short base portion 13 making contact along the entire surface with the surface of the back cover 6, whereby the adjacent divided frames 8 to 11 are favorably connected with no mis-insertion (misconnection) of the adjacent divided frames 8 to 11.

Also, when the divided frames 8 to 11 are arranged at the predetermined positions in this way, the through holes 27 and 28 that are formed in each attachment portion 20 of the divided frames 8 to 11 and the screw holes 3 of the display unit 1 come into communication, and by attaching the screws 25 to these through holes 27 and 28 and the screw holes 3, and furthermore tightening the screws 25 to the predetermined torque, the divided frames 8 to 11 are integrally fixed to the peripheral surface of the display unit 1. Then, by fitting the concealed label to the fitting recessed portion of each attachment portion, the assembly work of the display device is completed.

Also, at this time, the front wall portion 14 of each divided frame 8 to 11 is arranged in a state of covering the entire periphery of the front surface at the outer edge portion side of the display unit 1, and in the display device A in which the protective glass 30 is not provided, the frame housing 2 is attached in the state of the distal end (side end portion) of the turned back wall portion 15 abutting the front surface of the display unit 1 as shown in FIG. 12. Also, in the display device A in which the protective glass 30 is provided, as shown in FIG. 11, the frame housing 2 is attached in the state of a predetermined gap being opened between the distal end of the turned back wall portion 15 and the protective glass 30.

Here, the divided frames 8 to 11 may undergo thermal expansion and contraction due to the ambient temperature during assembly of the frame housing 2 and the temperature during operation of the display device A. Each divided frame 8 to 11 expand or contract due to such temperature changes, and the long base portion 12 expands or contracts by a larger amount of expansion or contraction than the short base portion 13. Also, the amount of expansion or contraction of the long base portion 12 increases the nearer to the distal end (end portion) side from the base end side that connects to the short base portion 13.

For this reason, conventionally, during the assembly work, the positions of the through holes of the attachment portions and the screw holes 3 of the display unit 1 shift, and so attachment of the divided frames became difficult, and stress sometimes arose in the divided frames that were attached. Also, even after assembly, stress sometimes arose in the divided frames due to the temperature during operation of the display device or the ambient temperature.

In contrast, in the frame housing 2 and the display device A of the present exemplary embodiment, the through holes 27 and 28 that are formed in each attachment portion 20 of the divided frames 8 to 11 are oblong holes. For this reason, even if expansion or contraction occurs in the divided frames 8 to 11 due to temperature fluctuations, when the divided frames 8 to 11 are installed on the peripheral surface of the display unit 1, due to the through holes 27 and 28 and the screw holes 3 being reliably in communication, the assembly work can be easily performed by inserting and screwing the screws 25 in these through holes 27 and 28 and the screw holes 3. Also, since the through holes 27 and 28 and the screw holes 3 are reliably in communication, the generation of stress caused by thermal expansion and contraction in the divided frames 8 to 11 in the state of the divided frames 8 to 11 being attached by the screws 25 to the display unit 1 is inhibited.

Also, in the present exemplary embodiment, by using flat-head screws for the screws 25 for attaching the divided frames 8 to 11 to the display unit 1, the planar bottom surface 25c of the head portion 25a presses and contacts the bottom surface 26a of the screw head housing recessed portion 26 of the attachment portion 20, whereby the divided frames 8 to 11 are screw fastened to the display unit 1. For this reason, as in the case of conventional constitutions in which the frame housing was attached to the display unit 1 using countersunk screws, countersunk screws passing through the frame housing 2 with thin walls made of plastic when tightened with a force greater than the specified torque, leading in the worst case to the need to replace the divided frames 8 to 11, does not arise.

Moreover, in the case of manufacturing the display device A by providing a protective glass 30 on the front face of the display unit 1, by inserting the screws 25 in the protective glass installation through-holes 27 and screwing them into the screw holes 3 of the display unit 1, the divided frames 8 to 11 are attached. Also, at this time, since the protective glass installation through-holes 27 are formed with the short axis S3 reduced compared to the normal-use through hole 28, play between the screws 25 and the through holes 27 when screw fastened is eliminated (becomes less). Thereby, the divided frames 8 to 11 are fixed to the display unit 1 in the state of a predetermined gap provided between the protective glass 30 of the display unit 1 and the distal end of the turned back wall portion 15 of the divided frames 8 to 11, and so the distal end of the turned back wall portion 15 causing damage by making contact with the protective glass 30 is reliably prevented.

Accordingly, in the frame housing 2 of the present exemplary embodiment and the display device A that includes it, since the through holes 27 and 28 that are formed in the attachment portions 20 of the divided frames 8 to 11 are made to be oblong holes, even in the case of expansion or contraction having occurred in the divided frames 8 to 11 due to thermal changes, it is possible to reliably bring the through holes 27 and 28 of the divided frames 8 to 11 and the screw holes 3 of the display unit 1 into communication, and so it is possible to readily perform the assembly work by inserting/screwing the screws into these through holes 27 and 28 and the screw holes 3. Moreover, since the through holes 27 and 28 and the screw holes 3 are reliably in communication in this way, and the through holes 27 and 28 are made to be oblong holes, even in the case of thermal deformation having occurred in the divided frames 8 to 11, it is possible to suppress the occurrence of stress.

Thereby, according to the frame housing 2 of the present exemplary embodiment and the display device A that includes it, it is possible to achieve an improvement in the manufacturing yield, and possible to achieve an improvement in the reliability of the display device A.

In addition, in the frame housing 2 of the present exemplary embodiment and the display device A that includes it, since the screws 25 for fixing the divided frames 8 to 11 are screws such as flat-head screws in which the bottom surface 25c of the head portion 25a has a planar shape, it is possible to screw fasten the divided frames 8 to 11 to the display unit 1 by the planar bottom surface 25c of the head portion 25a pressing and contacting the outer surface of the divided frames 8 to 11 (the bottom surface 26a of the screw head housing recessed portion 26). For that reason, it is possible to favorably fix and attach the divided frames 8 to 11 to the display unit 1 without the screws 25 piercing the divided frames 8 to 11 with thin walls made of plastic when tightened with a force greater than the specified torque as in the conventional case of using countersunk screws.

Moreover, since the protective glass installation through-hole 27 is formed with the length of the short axis S3 thereof less than that of the normal-use through hole 28, when screw fastening by using the protective glass installation through-hole 27, it is possible to eliminate (reduce) the play in the width direction T1 of the divided frames 8 to 11 between the screw 25 and the protective glass installation through-hole 27. Thereby, in the state of a predetermined gap being opened between the protective glass 30 that is provided on the front surface of the display unit 1, and the side end portion of the divided frames 8 to 11 that are arranged on the front surface side of the protective glass 30 (the distal end portion of the turned back wall portion 15), it is possible to reliably fix the divided frames 8 to 11 to the display unit 1, and it is possible to prevent the side end portions of the divided frames 8 to 11 from corning into contact with the protective glass 30 and thereby causing damage.

Also, by setting up the concealed label 23 to fit in the fitting recessed portion 24 that is formed in the attachment portion 20, it is possible to prevent the through holes 27 and 28 and the screws 25 from being exposed to the outside, and possible to enhance the design properties of the display device A. Also, in the case of being constituted in this manner, it is possible to make the outer surface of the concealed label 23 flush with the outer surface 21 of the divided frames 8 to 11, and since the head portion 25a of the screw 25 does not project to the outside from the outer surface 21 of the divided frames 8 to 11, it is possible to favorably use the display device A, which includes this frame housing 2 attached to the display unit 1, for multi-displays and the like.

Moreover, along with the connection portions 16 and 17, the engagement convex portion 18 and the engagement concave portion 19 are provided at the end portions of the divided frames 8 to 11. For this reason, when arranging the divided frames 8 to 11 along the peripheral surface of the display unit 1, by installing the adjacent divided frames 8 to 11 so that the connection portions 16 and 17 of the divided frames 8 to 11 overlap, while causing the engagement convex portion 18 to engage with the engagement concave portion 19, mis-insertion of adjacent divided frames 8 to 11 can be prevented. Thereby, it is possible to readily install each of the divided frames 8 to 11 at predetermined positions, and possible to favorably connect the adjacent divided frames 8 to 11.

Hereinabove, the frame housing of the present exemplary embodiment and one exemplary embodiment of the display device that includes it has been described. However, the present invention is not limited to the aforementioned exemplary embodiment, and appropriate modifications can be made within a range that does not depart from the gist thereof.

For example, in the exemplary embodiment, the through holes 27 and 28 of all of the attachment portions 20 of the divided frames 8 to 11 are formed as oblong holes. However, since the amount of expansion and contraction of the long base portion 14 is greater than that of the short base portion 13 when the divided frames 8 to 11 expand and contract due to temperature changes, the through holes 27 and 28 of the attachment portions 20 formed at the short base portion 13 and the base end side of the long base portion 14, that is to say, the through holes 27 and 28 of the portion where the amount of expansion and contraction is small and so no positional shifting with the screw holes 3 of the display unit 1 occurs or the positional shifting is permissible, may be formed as round holes in the same manner as previously done.

In addition, the two through holes 27 and 28 of each attachment portion 20 were both formed as oblong holes. However, one through hole may be formed as an oblong hole, while the other through hole may be formed as a circular hole.

### INDUSTRIAL APPLICABILITY

The present invention provides a frame housing and a display device that includes it, even in the case of thermal deformation having occurred in divided frames, enables the divided frames to be suitably attached by screw mounting to the display unit, and suppresses the generation of stress caused by thermal deformation.

### REFERENCE SYMBOLS

1 Display unit
2 Frame housing
3 Screw hole
4 Protective frame
5 Communication hole
6 Back cover
7 Communication hole
8 Divided frame
9 Divided frame
10 Divided frame
11 Divided frame
12 Long base portion
13 Short base portion
14 Front wall portion
15 Turned back wall portion
16 Connection portion
17 Connection portion
18 Engagement convex portion
19 Engagement concave portion
20 Attachment portion
21 Outer surface
22 Inner surface
23 Concealed label
24 Fitting recessed portion
25 Screw
25a Head portion
25b Shaft portion
25c Bottom surface
26 Screw head housing recessed portion
27 Through hole (protective glass installation through-hole)
28 Through hole (normal-use through hole)
30 Protective glass
A Display device
T1 Thickness direction
T2 Peripheral direction

1. A frame housing provided on a peripheral surface of a display unit, the frame housing comprising:
a plurality of divided frames including a plurality of attachment portions including a through hole used for screw-fastening to a screw hole provided in the peripheral surface of the display unit, and
the through hole being an oblong hole with a long-axis direction of the oblong hole arranged in a direction along the peripheral surface of the display unit.

2. The frame housing according to claim 1, further comprising:
a screw that is inserted into the through hole of the attachment portions and screwed into the screw hole of the display unit, and attaches the divided frames to the peripheral surface of the display unit, and
the screw includes a head portion, and a bottom surface of the head portion has a planar shape.

3. The frame housing according to claim 1, wherein
the attachment portions include a plurality of through holes including: a protective glass installation through-hole used when installing a protective glass on a front surface of the display unit; and a normal-use through hole used when not installing the protective glass, and
a length of a short axis of the protective glass installation through-hole is less than a length of a short axis of the normal-use through hole.

4. The frame housing according to claim 1, wherein
the attachment portions include: a fitting recessed portion that is recessed from an outer surface of the divided frames toward an inner surface of the divided frames and fits a concealed label; a screw head housing recessed portion that is recessed from a bottom surface of the fitting recessed portion toward the inner surface of the divided frame and houses a head portion of a screw; and the through holes that pass through from the bottom surface of the screw head housing recessed portion to the inner surface of the divided frames.

5. The frame housing according to claim 1, wherein
the divided frames further include connection portions that include thin walls projecting out in the peripheral direction of the display unit being provided at both end portion sides, and adjacent divided frames connect with the mutual connection portions being overlapped, and
the divided frames further include: an engagement convex portion that is provided at one end portion side of the divided frames, and projects from a distal end of the connection portion in the peripheral direction of the display unit; and an engagement concave portion that is provided at an other end portion side of the divided frames, and indents from a base end of the connection portions to the inside in the peripheral direction, and the adjacent divided frames connect with the mutual engagement convex portion and the engagement concave portion being engaged.

6. A display device comprising the frame housing according to claim 1, and the display unit.
